(19) United States
(12) Patent Application Publication
(10) Pub. No.: US 2025/0367818 A1
(43) Pub. Date: Dec. 4, 2025

(54) FRONT END ROBOT LEVELING JIG

(71) Applicant: ASM IP Holding B.V., Almere (NL)

(72) Inventor: Brian Bayliss, Fountain Hills, AZ (US)

(21) Appl. No.: 19/220,276

(22) Filed: May 28, 2025

Related U.S. Application Data
(60) Provisional application No. 63/654,739, filed on May 31, 2024.

(51) Int. Cl. B25J 9/00; B25J 11/00

(52) U.S. Cl. CPC B25J 9/0009; B25J 9/0087; B25J 11/0095

(57) ABSTRACT

A jig is provided for aligning an upper end effector and a lower end effector of a dual arm robot of a substrate processing system. The jig is configured to accommodate the lower end effector and the upper end effector is aligned with the lower end effector using the jig. Specifically, the jig includes an upper top surface and an upper side surface, and a lower top surface separated from a lower bottom surface by a lower side surface. The upper side surface and the lower top surface couple to form a right angle. Lower end effector aligns with the jig by coupling with the lower top surface and the upper side surface. After alignment of the lower end effector, upper end effector aligns with lower end effector by coupling with the jig.

### CROSS-REFERENCE TO RELATED APPLICATIONS

This application claims priority to and the benefits of U.S. Provisional Patent Application No. 63/654,739, filed on May 31, 2024, the contents of which is incorporated herein by reference in its entirety.

### FIELD OF INVENTION

The present disclosure generally relates to fabricating semiconductor devices, and more particularly to handling substrates used during the fabrication of semiconductor devices.

### BACKGROUND OF THE DISCLOSURE

A process of using a substrate processing apparatus includes a step of transporting a substrate from a Front Opening Unified Pod (FOUP) to a processing chamber via a substrate handling chamber and a load lock chamber using a robotic arm, or a step of transporting a substrate from a reaction chamber to another reaction chamber using a robotic arm. The robotic arm may be provided with an end effector for loading a substrate thereon and carrying the substrate from one chamber to another.

To prolong the use of these end effectors, the end effectors have to be removed from the substrate processing system for routine maintenance. However, when the end effectors are installed back on the substrate processing system, they may not be aligned with each other. In some conventional systems, the alignment process is performed by relying on human observation (i.e. eyeballing) without using any alignment tools. However, such a process may be prone to human error. Some conventional systems rely on metallic tools (such as a metal panel). However, this may result in particle contamination. Accordingly, there is a need in the art for systems and method that provide an alignment tool that improves alignment of the upper and lower end effector.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

A substrate processing system having a dual arm robot is provided. The dual robot includes an upper arm having an upper end effector and a lower arm having a lower end effector. Further, the substrate processing system includes a leveling jig that is configured to accommodate the lower end effector and align the upper end effector with lower end effector.

A method of installing a lower arm and an upper arm of a dual arm robot is provided. The method includes providing a jig that accommodates the lower end effector. The method further includes positioning lower end effector on the jig. Finally, the method includes aligning the upper end effector with the lower end effector using the jig.

A jig for alignment of a first end effector with a second end effector is provided. The jig includes an upper jig section having an upper top surface and an upper bottom surface, wherein the upper top surface and the upper bottom surface is separated by an upper side surface. The jig further includes a lower jig section having a lower top surface and a lower bottom surface, wherein the lower top surface and the lower bottom surface are separated by a lower side surface. The upper side surface includes a first upper side surface and a second upper side surface. The first upper side surface couples with the second upper side surface, and the first upper side surface is perpendicular to the second upper side surface. Further, the first upper side surface forms a right angle with the lower top surface, and the second upper side surface forms a right angle with the lower top surface.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 illustrates an overhead view of a substrate processing system 100 in accordance with embodiments described herein;

FIGS. 2A-2D illustrate various views of a jig that may be used in the substrate processing system of FIG. 1 in accordance with embodiments described herein;

FIGS. 3A-3C illustrate various views of alignment system that may be used in the substrate processing system of FIG. 1 in accordance with embodiments described herein;

FIGS. 4A-4D illustrate various embodiments of a teaching system that may be used in the substrate processing system of FIG. 1 in accordance with embodiments described herein;

FIG. 5 illustrates a flow diagram of a method of installing a lower arm and an upper arm of a dual arm robot of a substrate processing system of FIG. 1 in accordance with embodiments described herein.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

Reference will now be made to the drawings wherein like reference numerals identify similar structural features or aspects of the subject disclosure. The systems and methods of the present disclosure may be in semiconductor processing systems employed to fabricate semiconductor devices, such as in semiconductor processing systems employed to deposit material layers using chemical vapor deposition (CVD) and atomic layer deposition (ALD) techniques during the fabrication of logic and memory devices, though the present disclosure is not limited to any semiconductor processing operation or to the fabrication of any particular semiconductor device in general.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Wafers may be 200 millimeters in diameter, 300 millimeters, or even 450 millimeters in diameter. Substrates may be formed from one or more semiconductor materials including by way of non-limiting example silicon, silicon germanium, silicon oxide, gallium arsenide, gallium nitride and silicon carbide.

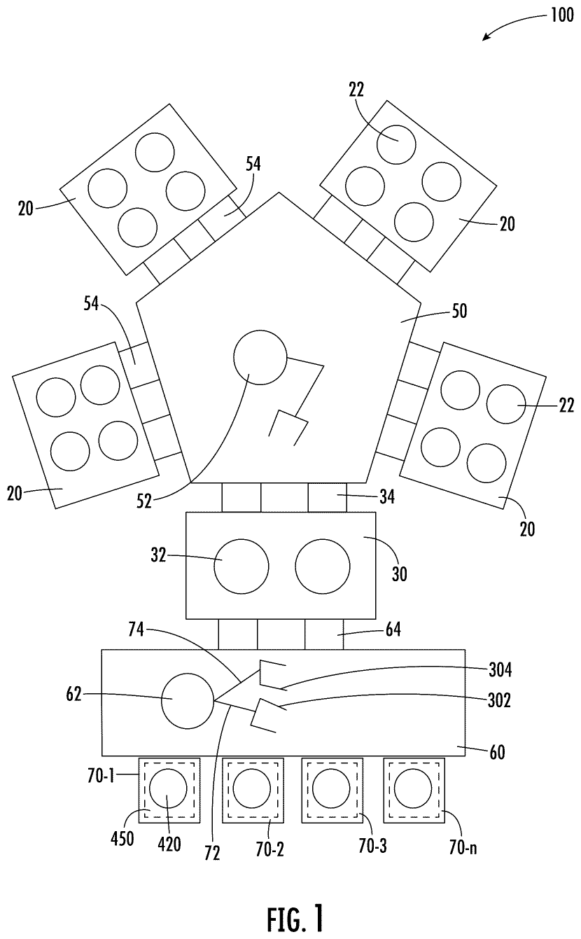

FIG. 1A illustrates an overhead view of a substrate processing system 100 in accordance with embodiments described herein. In the embodiment shown in FIG. 1, substrate processing system 100 includes a five faceted substrate handling chamber (SHC) 50 (although more or fewer facets could be provided in other examples of this technology). Four of these facets are coupled to respective substrate processing chambers (SPC) 20 via one or more gate valves 54. Further, each SPC is equipped to receive and process at least four substrates (substrate supports 22 are provided in the SPC 20).

The SHC 50 includes at least one robotic arm 52 that is used to move substrate into and out of the various SPCs 20. In use, a gate valve 54 is opened, an end effector of the robotic arm 52 extends through the open gate valve 54 to insert a substrate into or remove a substrate from an interior chamber of the SPC 20 (e.g. placing a substrate on or taking a substrate off one of the substrate supports 22). Once the robotic arm 52 is retracted from the SPC 20, the gate valve 54 is closed, thereby sealing the SPC 20 from the gate valve 54.

The substrate processing system 100 further includes a load lock (LL) module 30 is connected with the fifth facet of the SHC 50 by one or more gate valves 34. The LL module 30 include one or more substrate holding components 32 for holding substrate on the way into SHC 50 for further processing and on the way out of the SHC 50 after processing is complete. The end effector of robotic arm 52 moves through the gate valves 34 (when opened) to move substrate into the SHC 50 (for layer deposition and other processing) and out of SHC 50 (after processing is completed).

The LL module 30 is further coupled with an equipment front end module (EFEM) 60 via one or more additional gate valves 64. EFEM 60 further includes an EFEM robot 62. In exemplary embodiments, EFEM robot 62 is a dual arm robot with an upper arm 72 having an end effector 302 and a lower arm 74 having an end effector 304. End effectors 302 and 304 move through gate valve(s) 64 (when opened) to move substrate into LL module 30 (to eventually transport to processing chamber 20 for layer deposition and other processing) and out of LL module 30 (after processing is completed). Robot 62 is also configured to pick up new substrates for processing from one or more front opening unified pod (FOUP) 70 and returns processed substrates back to FOUP 70. In exemplary embodiments, multiple FOUPs (70-1, 70-2 . . . 70-n) may be included. In the example described herein, four FOUP 70-1 to 70-4 are coupled to EFEM 60. Although shown and described herein as having a specific architecture, it is to be understood and appreciated that substrate processing system 10 can have different architectures in other examples of the present disclosure (e.g. varying number of FOUPs 70, gate valves 34, 54, chambers 20, etc.), and remain within the scope of the present disclosure.

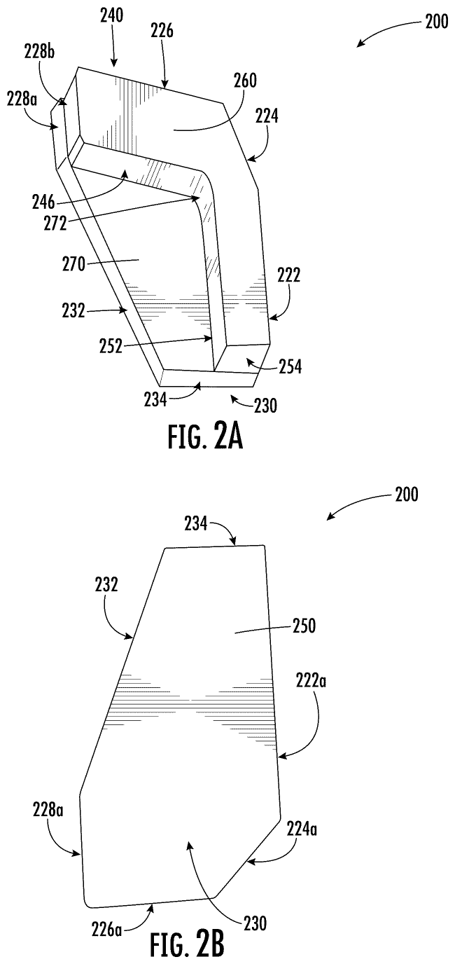

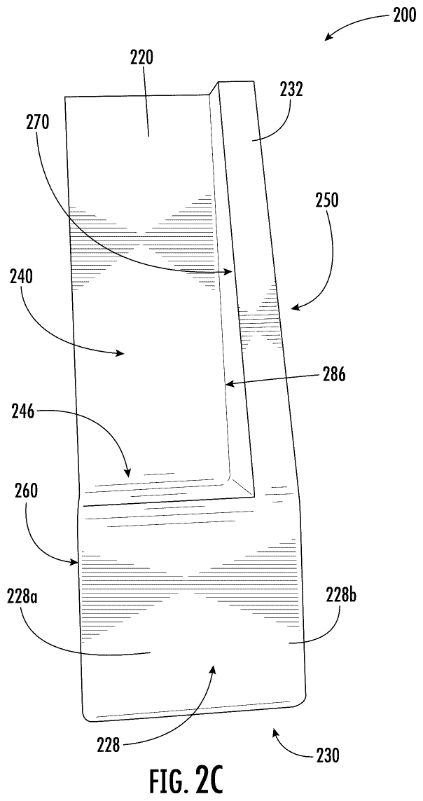

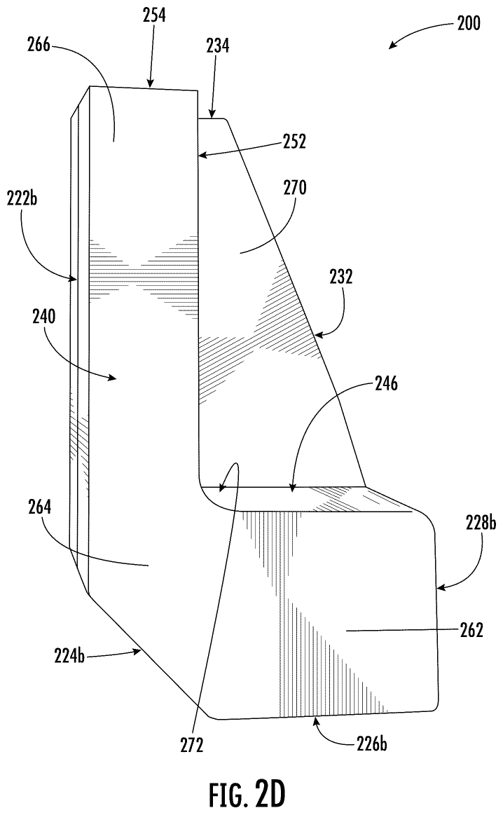

End effectors 302 and 304 can be removed from upper arm 72 and lower arm 74 for routine maintenance. After maintenance, end effectors 302 and 304 have to be installed back on robot 62. However, end effector 302 is no longer aligned with end effector 304. The two end effectors have to be aligned with each other prior to installation. In an event that the two end effectors are not aligned with each other, there is a possibility of wafer displacement during wafer transfer. Accordingly, FIGS. 2A to 4D provide systems and method to align and install end effector 302 and 304.

In the exemplary embodiments described herein, the lower end effector 304 is first fitted on lower arm 74. Specifically, the lower end effector 304 is fixed on lower arm 74 (i.e., by tightening the screws and torquing). Upper end effector 302 is also fitted on upper arm 72. However, unlike lower end effector 302, upper end effector 302 is not fixed on lower arm 74. In other words, upper end effector 302 remains sufficiently flexible to adjust and align as appropriate. A jig (such as jig 200) formed to accommodate lower end effector 304 can now be used to first set lower end effector 304 in place. After lower end effector 304 is positioned on the jig, upper end effector 302 is adjusted to align with the jig and consequently with lower end effector 304. Once both lower end effector 302 and upper end effector 304 are in alignment with jig 200 (and with each other), upper end effector 304 can be fixed to upper arm 72 (for example, by tightening the screws to the correct torque specification or any other conventional means of fixing).

FIGS. 2A-2D illustrate various views of jig 200 according to an example. FIG. 2A illustrates a perspective view of jig 200. FIG. 2B illustrates a bottom view of jig 200. FIG. 2C illustrates a side view of jig 200. FIG. 2D illustrates a top view of jig 200. Jig 200 is used to align upper arm 72 with lower arm 74. FIGS. 2A-2D illustrate one embodiment of jig 200; however, jig 200 may be designed of any other shape appropriate to align end effectors 302 and 304 of upper arm 72 and lower arm 74, respectively.

FIG. 2A illustrates a perspective view of jig 200. In exemplary embodiments, jig 200 includes an upper jig section 240 and a lower jig section 230. In exemplary embodiments, upper jig section 240 and lower jig section 230 may be different pieces that are adjoined together. In exemplary embodiments, upper jig section 240 and lower jig section 230 is formed as a single piece (that is, formed from a single block, formed as a single piece using technology such as 3D printing, etc.). As shown in FIG. 2A, lower jig section 230 includes a lower top surface 270, a lower bottom surface 250 and at least one lower side surface 282. In exemplary embodiments, lower side surface 282 may be a single surface (for example, circular) without any edges. In exemplary embodiments, lower side surface 282 may include multiple surfaces (for example, forming a polygonal shape (for example, as shown in FIG. 2B)). Lower top surface 270 and lower bottom surface 250 are parallel to each other separated by lower side surface 282.

Further, upper jig section 240 includes an upper bottom surface 286, an upper top surface 260, and at least one upper side surface 284. In exemplary embodiments, upper side surface 284 may include multiple side surfaces (for example, forming a polygonal shape, an “L” shape, etc. (for example, as shown in FIG. 2D)). Upper bottom surface 286 and upper top surface 260 are separated by upper side surface 284.

FIG. 2B illustrates a bottom view of jig 200. Jig 200 includes a bottom surface 250 that is part of lower jig section 230. Bottom surface 250 is defined by a polygonal or a circular shape. In exemplary embodiments, bottom surface 250 is defined by a plurality of lower side surfaces. In exemplary embodiments, bottom surface 250 is defined by a four-sided polygon (i.e. a rectangular surface).

In the example shown in FIGS. 2A and 2B, bottom surface 250 is defined by six sided polygon. A first lower side surface 222a connects with a second lower side surface 224a at a common edge. In exemplary embodiments, first lower side surface 222a and second lower side surface 224a form an obtuse angle. A third lower side surface 226a connects with second lower side surface 224a at a common edge. In exemplary embodiments, second lower side surface 224a and third lower side surface 226a form an obtuse angle. Third lower side surface 226a connects with a fourth lower side surface 228a at a common edge. In exemplary embodiments, third lower side surface 226a and fourth lower side surface 228a form a right angle. In further exemplary embodiments, fourth lower side surface 228a is parallel to first lower side surface 222a. A fifth lower side surface 232a connects with fourth lower side surface 228a at a common edge. In exemplary embodiments, fourth lower side surface 228a and fifth lower side surface 232a form an obtuse angle. A sixth lower side surface 234a connects with fifth lower side surface 232a at a common edge. In exemplary embodiments, sixth lower side surface 234a and fifth lower side surface 232a form an obtuse angle. In further exemplary embodiments, sixth lower side surface 234a is parallel to third lower side surface 226a. Finally, in the example shown in FIG. 2A, sixth lower side surface 234a connects back to first lower side surface 222a. In exemplary embodiments, first lower side surface 222a and sixth lower side surface 234a form a right angle. Accordingly, in the examples shown in FIGS. 2A-2D, lower side surfaces 222a, 224a, 226a, 228a, 232, and 234 define bottom surface 250.

Referring now to FIG. 2D, a top view of jig 200 is illustrated. Jig 200 includes a top surface 260 that is part of upper jig section 240. Top surface 260 is defined by an “L” shaped polygon. In exemplary embodiments, top surface 260 is defined by a plurality of upper side surfaces. In the example shown in FIGS. 2A and 2D, top surface 260 is defined by at least a seven-sided polygon. A first upper side surface 222b connects with a second upper side surface 224b at a common edge. In exemplary embodiments, first upper side surface 222b and second upper side surface 224b form an obtuse angle. A third upper side surface 226b connects with second upper side surface 224b at a common edge. In exemplary embodiments, second upper side surface 224b and third upper side surface 226b form an obtuse angle. Third upper side surface 226b connects with a fourth upper side surface 228b at a common edge. In exemplary embodiments, third upper side surface 226b and fourth upper side surface 228b form a right angle. In further exemplary embodiments, fourth upper side surface 228b is parallel to first upper side surface 222b. A fifth upper side surface 246 connects with fourth upper side surface 228b at a common edge. In exemplary embodiments, fifth upper side surface 246 and fourth upper side surface 228b form a right angle. In further exemplary embodiments, fifth upper side surface 246 is parallel to third upper side surface 226b. In exemplary embodiments, fifth upper side surface 246 connects with sixth upper side surface 252. In exemplary embodiments, fifth upper side surface 246 and sixth upper side surface 252 are perpendicular. In further exemplary embodiments, sixth upper side surface 252 is parallel to first upper side surface 222b. In some exemplary embodiments, fifth upper side surface 246 and sixth upper side surface 252 are connected via a seventh side surface 272. In further exemplary embodiments, seventh upper surface 272 is a rounded corner surface connecting fifth upper side surface 246 and sixth upper side surface 252. In exemplary embodiments, sixth upper side surface 252 connects with eighth upper side surface 254 at a common edge. In exemplary embodiments, eighth upper side surface 254 and sixth upper side surface 252 form a right angle. In further exemplary embodiments, eighth upper side surface 254 is parallel to third (and fifth) upper side surface 254. Finally, in the example shown in FIGS. 2A and 2D, eighth upper side surface 254 connects back to first upper side surface 222b. In exemplary embodiments, first upper side surface 222b and eight upper side surface 254 form a right angle. Accordingly, in the examples shown in FIGS. 2A-2D, upper side surfaces 222b, 224b, 226b, 228b, 246, 252 and 254 define top surface 270.

FIG. 2C illustrates a side view of jig 200. Upper bottom surface 286 meets with lower top surface 270. As shown in FIGS. 2A, 2C and 2D, lower side surface 222a and upper side surface 222b align to form side 222. Similarly, lower side surface 224a and upper side surface 224b align to form side 224. Lower side surface 226a and upper side surface 226b align to form side 226. In exemplary embodiments, lower side 228a and 228b align to form side 228. In exemplary embodiments, sides 222, 224, 226 and 228 are formed by adjoining upper bottom surface 286 of upper jig section 240 with lower top side 270 of lower jig section 230. In exemplary embodiments, upper jig section 240 and lower jig section 230 do not have to be adjoined at two separate sections as jig 200 may be formed from a single block.

In exemplary embodiments, height of lower jig section 230 is approximately 1 mm. In exemplary embodiments, height of upper jig section 240 is approximately 4 mm. In exemplary embodiments, length of side 222 is within a range of 10 mm to 16 mm. In exemplary embodiments, length of side 222 is 15 mm. In exemplary embodiments, length of side 222 is 11 mm. In exemplary embodiments, height of side 222 is approximately 5 mm. In exemplary embodiments, side 224 is within a range of 3 mm to 5 mm. In exemplary embodiments, length of side 224 is approximately 4 mm. In exemplary embodiments, height of side 224 is approximately 5 mm. In exemplary embodiments, length of side 226 is within a range of 8 mm to 9 mm. In exemplary embodiments, length of side 226 is approximately 8.5 mm. In exemplary embodiments, length of side 226 is 5.7 mm. In exemplary embodiments, height of side 226 is approximately 5 mm. In exemplary embodiments, length of side 228 is within a range of 4 mm to 5 mm. In exemplary embodiments, length of side 228 is approximately 4.7 mm. In exemplary embodiments, height of side 228 is approximately 5 mm.

In exemplary embodiments, length of side 246 is within a range of 4 mm and 6 mm. In exemplary embodiments, length of side 246 is approximately 5.7 mm. In exemplary embodiments, height of side 246 is approximately 4 mm. In exemplary embodiments, length of side 252 is within a range of 8 mm and 11 mm. In exemplary embodiments, length of side 252 is approximately 10.3 mm. In exemplary embodiments, height of side 252 is approximately 4 mm. In exemplary embodiments, length of side 254 is within a range of 2 mm and 3 mm. In exemplary embodiments, length of side 254 is approximately 2.8 mm. In exemplary embodiments, height of side 254 is approximately 4 mm.

In exemplary embodiments, length of side 232 is within a range of 10 mm and 12 mm. In exemplary embodiments, length of side 232 is approximately 11 mm. In exemplary embodiments, height of side 232 is approximately 1 mm. In exemplary embodiments, length of side 234 is within a range of 4 mm to 5 mm. In exemplary embodiments, length of side 234 is approximately 4.5 mm. In exemplary embodiments, height of side 234 is approximately 1 mm. Accordingly, jig 200 is defined by upper top surface 260, lower top surface 270, lower bottom surface 250, sides 222, 224, 226, 228, 232, 234, 246, 252, and 254.

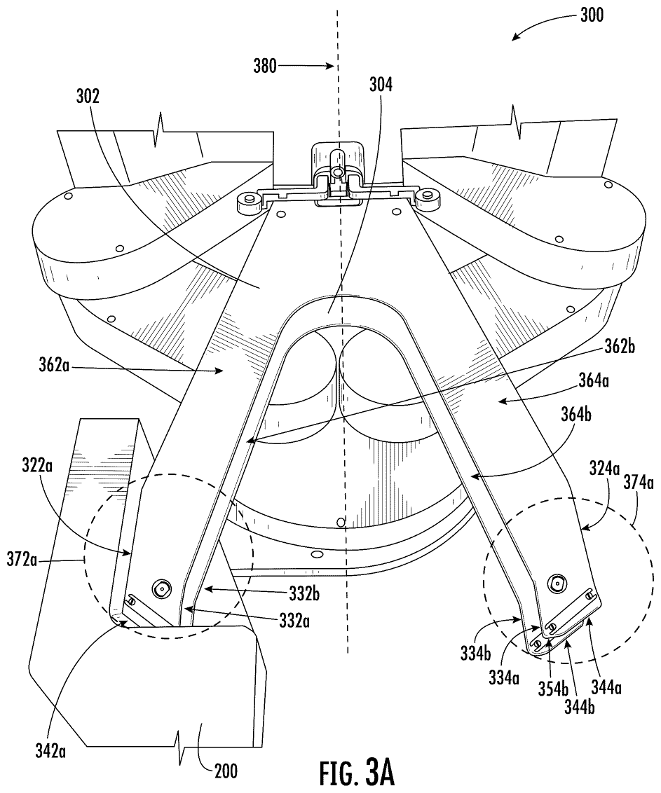

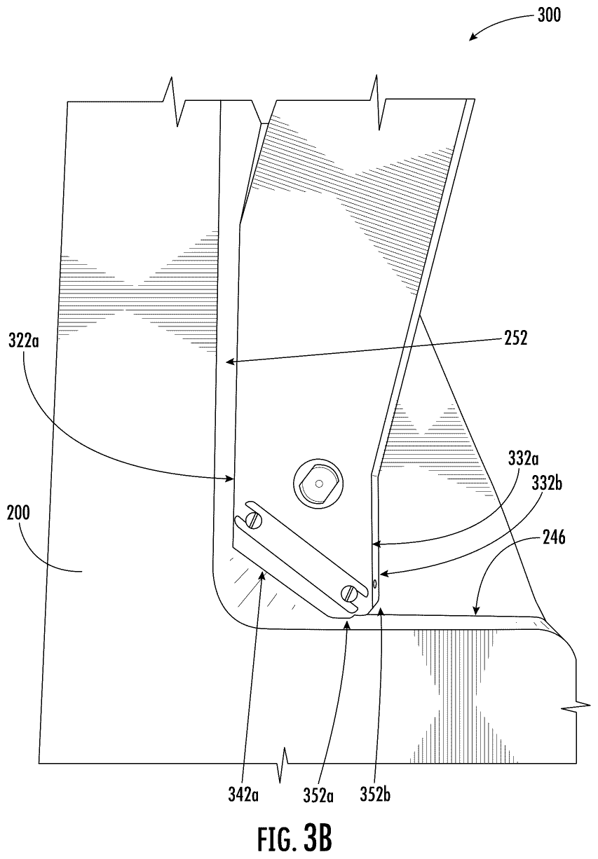

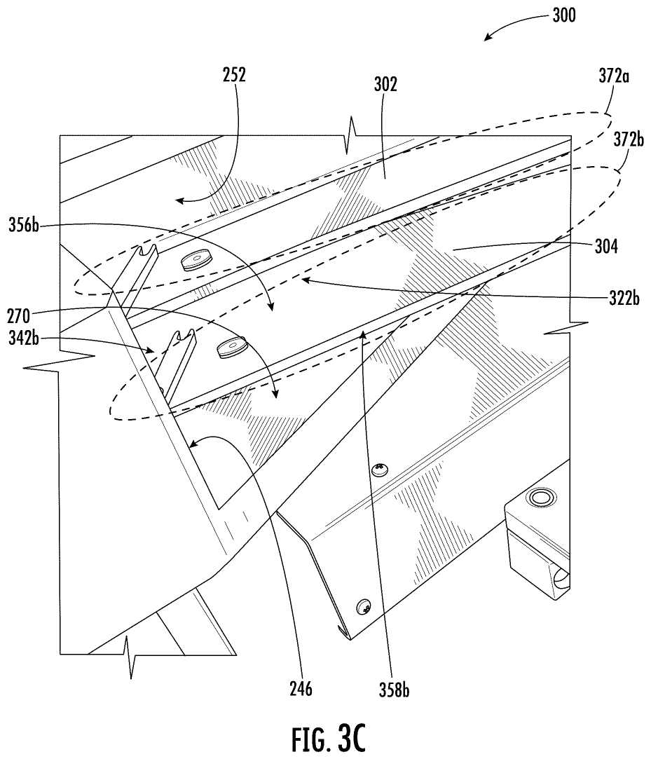

Referring now to FIGS. 3A-3C, an exemplary embodiment of alignment system 300 is illustrated. FIGS. 3A and 3B illustrate top views of alignment system 300. FIG. 3C illustrates a perspective view of alignment system 300. Alignment system 300 includes a dual arm robot, such as dual arm robot 62, having an upper arm, such as upper arm 72 and a lower arm, such as lower arm 74. As shown in FIGS. 1 and 3A, upper arm 72 includes an upper end effector 302, and lower arm 74 includes a lower end effector 304. As further shown in FIG. 3A, end effector 302 includes two fingers, an upper left finger 362a and an upper right finger 364a. Similarly, end effector 304 includes two fingers, a left lower finger 362b and lower right finger 364b. As shown in FIG. 3A, left finger 362a includes an outer edge 322a and an inner edge 332a. Similarly, left finger 362b includes an outer edge 322b and an inner edge 332b. Further, right finger 364a includes an outer edge 324a and an inner edge 334a. Similarly, right finger 364b includes an outer edge 324b and an inner edge 334b. As shown in FIG. 3A, left fingers 362a and left fingers 362b have a similar design. Further, right fingers 364a and 364b have a similar design. As further shown in FIG. 3A, left finger 362a has a similar design as right finger 364a but are oriented in opposite directions with respect to axis 380, creating a symmetrical design of end effector 302. Similarly, left finger 362b has a similar design as right finger 364b but are oriented in opposite directions with respect to axis 380, creating a symmetrical design of end effector 304.

Each of the fingers 362a, 362b, 364a and 364b include similar features. As an example, a finger 364a is described here in further detail. As shown in FIG. 3A, finger 364a includes an outer edge 324a. Fingers 364b, 362a and 362b include outer edges 324b (not shown), 322a, and 322b, respectively, that are similar to outer edge 324a. Further, finger 364a includes an inner edge 334a. Fingers 364b, 362a, and 362b include inner edges 334b, 332a and 332b, respectively, that are similar to inner edge 334a.

Finger 364a includes a front edge 344a. As shown in FIG. 3A, front edge 344a connects with outer edge 324a and inner edge 334a. Accordingly, outer edge 324a, inner edge 334a and front edge 344a define the end tip 374a of finger 364a. In exemplary embodiments, at least a portion of front edge 344a is perpendicular to outer edge 324a. In exemplary embodiments, at least a portion of front edge 344a is perpendicular to inner edge 334a. In exemplary embodiments, front edge 344a is not perpendicular to outer edge 324a. In exemplary embodiments, front edge 344a is not perpendicular to inner edge 334a. In the example shown in FIG. 3A, front edge 344a forms an obtuse angle with outer edge 324a. Further, front edge 344a includes a front edge section 354a that connects and forms a right angle with inner edge 334a. Fingers 364b, 362a and 362b include front edges 344b, 342a and 342b, respectively, that are similar to front edge 344a. As shown in FIG. 3A, outer edge 322a, 332a and front edge 342a define the end tip 372a of finger 362a. Similarly, outer edge 322b, inner edge 332b and front edge 342b define an end tip 372b of finger 362b, and outer edge 324b, inner edge 334b and front edge 344b define an end tip of finger 364b.

As further seen in FIGS. 3A-3C, jig 200 is used to align upper end effector 302 with lower end effector 304. The exemplary embodiments shown herein illustrate a jig 200 that is designed to align left fingers 362a and 362b with each other, which will consequently result in alignment of end effector 302 and 304. However, a similar jig may be designed to align right fingers 364a and 364b to align end effector 302 and 304 with each other.

As seen in FIGS. 3B and 3C, jig 200 is set in place with an end tip 372b of left lower finger 362b. As illustrated in FIG. 3C, left lower finger 362b includes a left lower bottom surface 358b and a left lower top surface 356b. Left lower bottom surface 358b and left lower top surface 356b are separated by edges 322b, 332b and 342b. During alignment, jig 200 is set such that left lower bottom surface 358b of left lower finger 362b lays flat on surface 270. Further, surface 252 is brought against outer edge 322b such that it pushes against surface 252. In exemplary embodiments, surface 246 is further set such that at least a part of front edge 342b pushes against surface 246. In exemplary embodiments, front edge 342b includes a front edge section 352b that pushes against surface 246. Accordingly, left lower finger 362b is set in place using jig 200.

After left lower finger 362b is in place, left upper finger 362a is aligned with left lower finger 362b using jig 200. As seen in FIG. 2B, left upper finger 362a is adjusted such that an outer edge 322a pushes against surface 252 and at least a part of front edge 342a pushes against surface 246. In the example shown in FIG. 3B, front edge 342a includes a front edge section 352a that pushes against surface 246. Accordingly, outer edge 322a is aligned with outer edge 322b, and front edge 342a is aligned with front edge 342b. Consequently, upper end effector 302 is aligned with lower end effector 304, and upper end effector 302 can be installed in place. That is, after aligning the upper end effector 302 with lower end effector 304, upper arm 72 can be tightened.

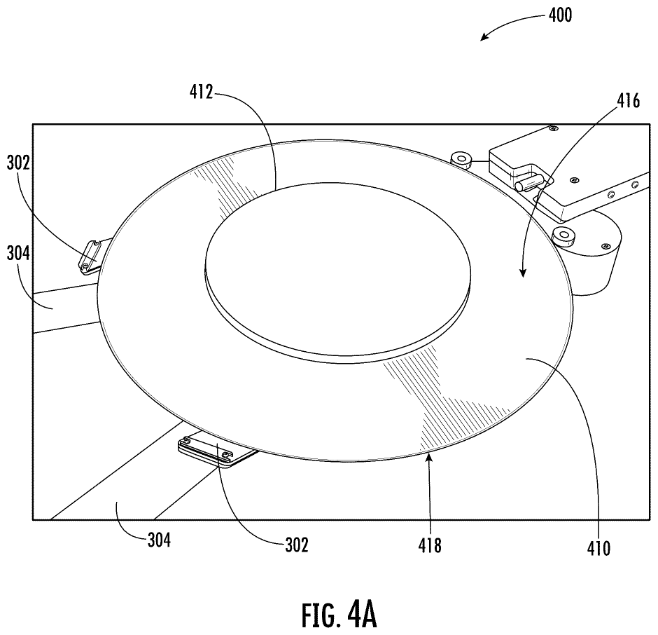

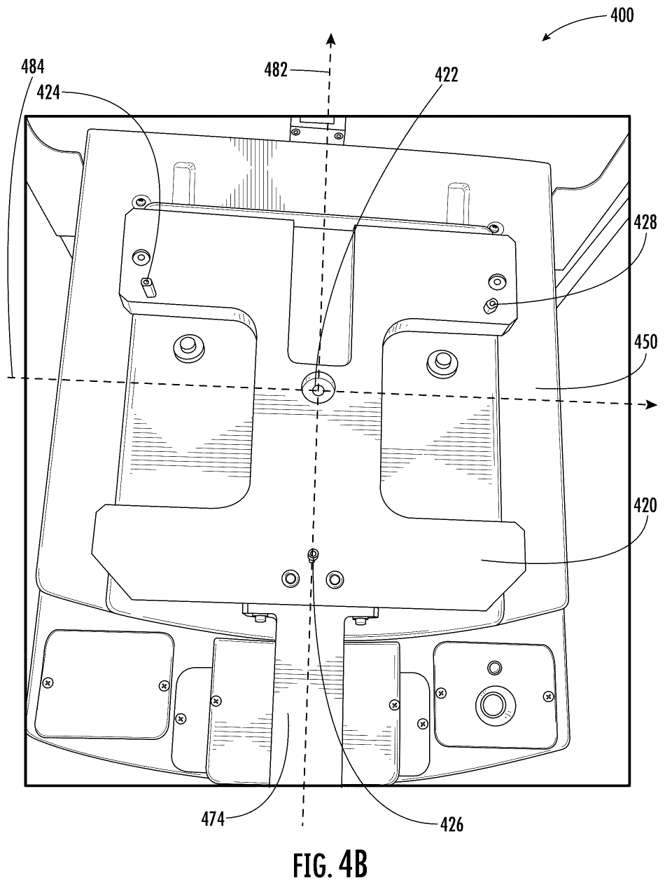

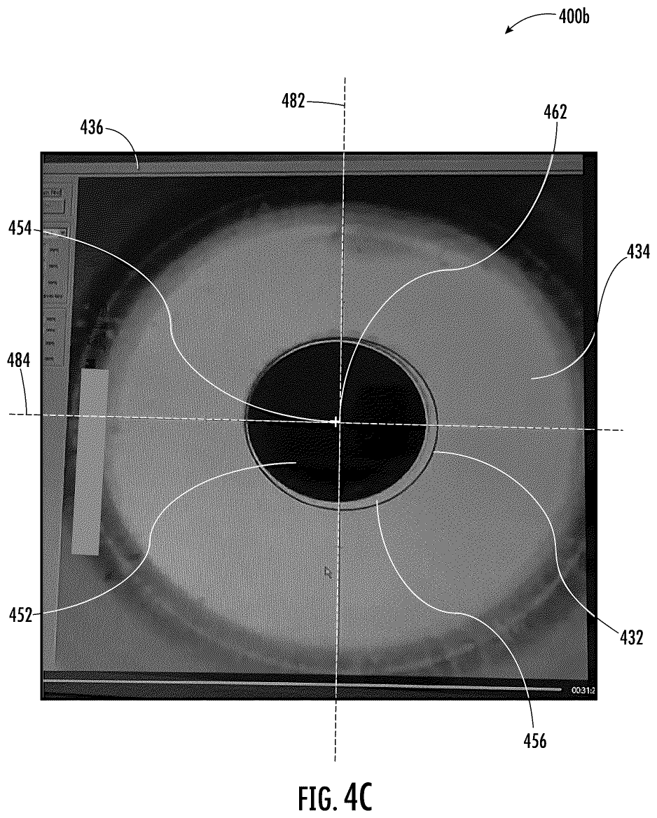

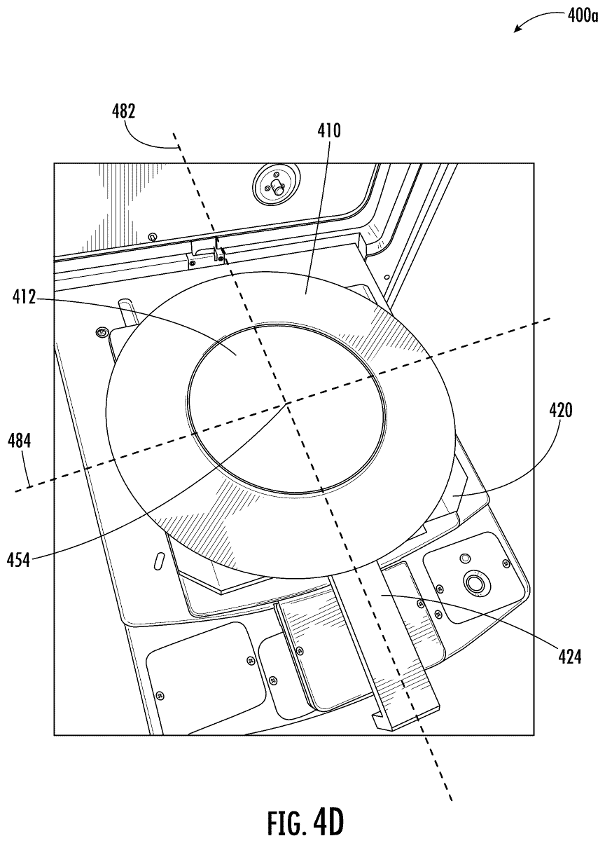

FIGS. 4A-4D illustrate a teaching system 400 that includes various steps of teaching upper arm 72 the parameters (i.e. theta θ, reach and height Z) for wafer placement position in given slots in FOUP 70. Specifically, FIG. 4A illustrates placement of a camera wafer 410 on end effector 302 of upper arm 72. Camera wafer 410 is generally the same size as a conventional wafer substrate. Camera wafer includes a top surface 416 and a bottom surface 418. Camera wafer 410 includes a camera section 412. Camera section 412 controls a camera (that is visible from bottom surface 418) that presents a downward view. That is, camera wafer 410 captures images below end effector 302 on which it is placed. In exemplary embodiments, camera is located in the center of camera wafer 410. After placing camera wafer 410 on end effector 302, upper arm 72 is moved to drop the camera wafer on a teaching jig 420 on a load port 450.

FIG. 4B illustrates a top view 400a of teaching jig 420. As shown in FIG. 4B, teaching system 400 includes a load port 450. Teaching jig 420 is placed on load port 450, and camera wafer 410 is to be dropped on testing jig 420. As shown in FIG. 4B, teaching jig 420 includes a pin hole 422 located at an intersection of axis 482 and axis 484. In exemplary embodiments, axes 482 and 484 are perpendicular to each other and pin hole 422 can be considered to be at coordinates (0, 0). Robot 62 is controlled to move end effector 302 over teaching jig 420. The downward view is then visible from camera wafer 410 to reveal a top view of teaching jig 420.

FIG. 4C illustrates a downward view 400b visible from camera located in camera wafer 410 displayed through an application. Downward view 400b of the camera is visible to the user on display 436 using an application and/or a software. As shown in FIG. 2C, the application includes a target spot 432 and an actual spot 452. In exemplary embodiments, target spot 432 is a circular spot represented by a circle having a center 462 at coordinate (0, 0) along axes 482 and 484. Accordingly, center 462 of target spot 432 is aligned with pin hole 422. Thus, target spot 432 defines a spot for wafer placement position on teaching jig 420.

In exemplary embodiments, actual spot 452 is a circular spot represented by a center 454. Actual spot 452 is approximately the same size as target spot 432. Actual spot 452 represents actual placement of camera wafer 410 on end effector 302 over teaching jig 420. In the example shown in FIG. 4C, actual spot 452 is not perfectly aligned with target spot 432. Specifically, actual spot 452 is offset from target spot 432 by an offset difference 456. Accordingly, end effector 302 has to be adjusted to align center 454 with a center of target spot 432, and consequently align with pin hole 422. After actual spot 452 is aligned with target spot 432, upper arm 72 can drop camera wafer 410 on teaching jig 420.

FIG. 4D illustrates a top view 400a wherein camera wafer 410 is placed on teaching jig 420. In the exemplary embodiment shown in FIG. 4D, center 454 of camera wafer 410 is aligned with pin hole 422 and camera wafer 410 is dropped on teaching jig 420. The three pins 424, 426 and 428 on teaching jig 420 represent the measurements for slot one of FOUP 70. That is, the theta, reach and Z-height for placement of wafer on slot one of FOUP 70 are measured based on the placement of camera wafer 410 over pins 424, 426 and 428. After camera wafer 410 is dropped on teaching jig 420, the parameters (theta, reach and Z-height) of robot 62 are captured by the camera. These parameters are then uploaded and, in some examples, stored in a memory for calculating wafer placement parameters for lower arm 74. By teaching the upper arm 72 and calculating for lower arm 74, parameters for all 25 slots for FOUP 70 are computed and stored. Because the lower end effector 304 is aligned with upper end effector 302, and subsequently lower arm 74 is aligned with upper arm 72 using jig 200, data received (on parameters such as theta, reach and Z-height) from the upper arm teach can be used to calculate lower arm teach position for lower arm 742

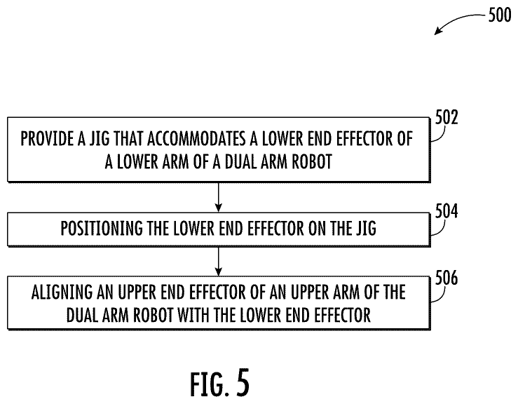

FIG. 5 illustrates a method 500 of installing a lower arm and an upper arm of a dual arm robot, such as robot 62 of a semiconductor processing system, such as semiconductor processing system 10. Method 500 includes providing a jig, such as jig 200, that accommodates the lower end effector, such as lower end effector 304, as shown with box 502. In exemplary embodiments of method 500, jig includes a lower jig section, wherein the lower jig section, such as lower jig section 230. In exemplary embodiments, lower jig section includes a lower top surface, such as lower top surface 270, a lower bottom surface, such as lower bottom surface 250, and a lower side surface. The lower top surface and the lower bottom surface are separated by the lower side surface.

In exemplary embodiments of method 500, jig includes an upper jig section, such as upper jig section 240. In exemplary embodiments, upper jig section bars an upper top surface, such as top surface 260, an upper bottom surface and an upper side surface. The upper top surface and the upper bottom surface is separated by the upper side surface. In exemplary embodiments, the upper side surface includes a first upper side surface, such as side surface 252 and a second upper side surface, such side surface 246. The first upper side surface couples with the second upper side surface, and the first upper side surface is perpendicular to the second upper side surface. Further, the first upper side surface forms a right angle with the lower top surface, and the second upper side surface forms a right angle with the lower top surface.

Method 500 further includes positioning the lower end effector on the jig, as shown in box 504. In exemplary embodiments, positioning the lower end effector on the jig includes placing the lower end effector on the lower top surface such that a lower end effector bottom surface of the lower end effector couples with the lower top surface. In exemplary embodiments, method 500 further includes coupling a lower outer edge of the lower end effector with the first upper side surface and coupling a lower front edge of the lower end effector with the second upper side surface. In exemplary embodiments of method 500, aligning the upper end effector with the lower end effector includes coupling an upper outer edge of the upper end effector with the first upper side surface and coupling an upper front edge of the upper end effector with the second upper side surface.

Method 500 further includes aligning the upper end effector, such as the upper end effector 302, with the lower end effector, as shown in box 506. In exemplary embodiments, method 500 further includes tightening the upper end effector to align with the lower end effector.

In exemplary embodiments, method 500 further includes teaching wafer placement positions to the upper arm and calculating wafer placement positions to the lower arm (as shown in FIGS. 4A-4D). In exemplary embodiments of method 500, teaching wafer placement positions to the upper arm includes placing a camera wafer on the aligned upper end effector, wherein the camera wafer is configured to capture a downward view from the camera wafer. In exemplary embodiments, method 500 further includes holding the upper end effector over a bottom slot of a front opening unified pod.

In exemplary embodiments, method 500 further includes adjusting upper end effector for proper placement of camera wafer on the bottom slot based on the downward view. In exemplary embodiments, adjusting the upper end effector further includes aligning a camera center of the camera wafer with a pinhole on the bottom slot of the front opening unified pod. In exemplary embodiments, method 500 further includes dropping the camera wafer on the bottom slot and calculating wafer placement position based on the downward view.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A substrate processing system comprises:
a dual arm robot comprising:
an upper arm having an upper end effector;
a lower arm having a lower end effector; and
a leveling jig configured to accommodate the lower end effector and align the upper end effector with the lower end effector.

2. The substrate processing system of claim 1, wherein the leveling jig comprises:
an upper jig section having an upper top surface and an upper side surface; and
a lower jig section having a lower top surface and a lower bottom surface, wherein the lower top surface and the lower bottom surface are separated by a lower side surface;
wherein the upper side surface is coupled to the lower top surface to form a right angle between the at least a portion of the upper side surface and the lower top surface.

3. The substrate processing system of claim 2, wherein the upper jig section has an upper bottom surface, wherein the upper top surface and the upper bottom surface is separated by an upper side surface, and wherein the upper jig section is attached to the lower jig section such that the upper bottom surface is attached to the lower top surface.

4. The substrate processing system of claim 3, wherein the upper jig section forms an “L” shape.

5. The substrate processing system of claim 3, wherein the lower side surface comprises a plurality of side surfaces.

6. The substrate processing system of claim 5, wherein the lower side surface comprises:
a first lower side surface;
a second lower side surface coupled to the first lower side surface;
a third lower side surface coupled to the second lower side surface; and
a fourth lower side surface coupled to the third lower side surface;
wherein the first lower side surface is parallel to the third lower side surface, and at least a portion of the second lower side surface is parallel to at least a portion of the fourth lower side surface.

7. The substrate processing system of claim 6, wherein the upper side surface comprises:
a first upper side surface;
a second upper side surface coupled to the first upper side surface, wherein at least a portion of the second upper side surface is perpendicular to the first upper side surface;
a third upper side surface coupled to the second upper side surface, wherein the third upper side surface is parallel to the first upper side surface;
a fourth upper side surface coupled to the third upper side surface, wherein the fourth upper side surface forms a right angle with the third upper side surface;
a fifth upper side surface coupled to the fourth upper side surface, wherein the fifth upper side surface is perpendicular with the fourth upper side surface, and wherein the fifth upper side surface is parallel to the third upper side surface; and
a sixth upper side surface coupled to the fifth upper side surface and the first upper side surface, wherein at least a portion of the sixth upper side surface is parallel with the second upper side surface, and wherein at least a portion of the sixth upper side surface is perpendicular to the first upper side surface.

8. The substrate processing system of claim 7, wherein the plurality of side surfaces comprising:
a second side surface comprising the second upper side surface and the second lower side surface;
a third side surface comprising the third upper side surface and the third lower side surface;
wherein the fifth upper side surface is coupled with the lower top surface such that the fifth upper side surface forms a right angle with the lower top surface; and
wherein the sixth upper side surface is coupled with the lower top surface such that at least a portion of the sixth upper side surface forms a right angle with the lower top surface.

9. The substrate processing system of claim 8, wherein the lower top surface is configured to couple with a lower end effector bottom surface of the lower end effector, wherein the sixth upper side surface is configured to couple with a lower outer edge of the lower end effector, and wherein the fifth upper side surface is configured to couple with a front edge of the lower end effector.

10. The substrate processing system of claim 7, wherein length of first upper side surface is less than length of first lower side surface.

11. The substrate processing system of claim 7, wherein the fourth lower side surface comprises:
a fifth lower surface that is coupled to the third lower surface; and
a sixth lower surface that is coupled to the first lower surface.

12. The substrate processing system of claim 3, wherein height of upper side surface is 4 mm.

13. The substrate processing system of claim 2, wherein height of lower side surface is 1 mm.

14. A method of installing a lower arm and an upper arm of a dual arm robot, the method comprising:
providing a jig that accommodates a lower end effector of the lower arm;
positioning the lower end effector on the jig; and
aligning an upper end effector of the upper arm with the jig and the lower end effector.

15. The method of claim 14, wherein providing a jig that accommodate the lower end effector comprises providing a jig that comprises:
a lower jig section, wherein the lower jig section comprises a lower top surface, a lower bottom surface and a lower side surface, wherein the lower top surface and the lower bottom surface is separated by the lower side surface;
an upper jig section, wherein the upper jig section comprises an upper top surface, an upper bottom surface and an upper side surface, wherein the upper top surface and the upper bottom surface is separated by the upper side surface;
wherein the upper side surface comprises a first upper side surface and a second upper side surface, wherein the first upper side surface couples with the second upper side surface, and wherein the first upper side surface is perpendicular to the second upper side surface; and
wherein the first upper side surface forms a right angle with the lower top surface, and wherein the second upper side surface forms a right angle with the lower top surface.

16. The method of claim 15,
wherein positioning the lower end effector on the jig further comprises:
placing the lower end effector on the lower top surface such that a lower end effector bottom surface of the lower end effector couples with the lower top surface;
coupling a lower outer edge of the lower end effector with the first upper side surface; and
coupling a lower front edge of the lower end effector with the second upper side surface; and
wherein aligning the upper end effector with the lower end effector further comprises:
coupling an upper outer edge of the upper end effector with the first upper side surface; and
coupling an upper front edge of the upper end effector with the second upper side surface.

17. The method of claim 14 further comprises tightening the upper end effector to align with the lower end effector.

18. The method of claim 14, further comprising:
teaching wafer placement parameters to the upper arm; and
calculating wafer placement parameters for the lower arm.

19. The method of claim 18, wherein teaching wafer placement positions to the upper arm comprises:
placing a camera wafer on the aligned upper end effector, wherein the camera wafer is configured to capture a downward view from the camera wafer;
holding the upper end effector over a teaching jig;
adjusting upper end effector for proper placement of camera wafer on the teaching jig based on the downward view;
dropping the camera wafer on the teaching jig; and
storing wafer placement position based on the downward view.

20. A jig for alignment of a first end effector with a second end effector comprises:
an upper jig section having an upper top surface and an upper bottom surface, wherein the upper top surface and the upper bottom surface is separated by an upper side surface; and
a lower jig section having a lower top surface and a lower bottom surface, wherein the lower top surface and the lower bottom surface are separated by a lower side surface;
wherein the upper side surface comprises a first upper side surface and a second upper side surface, wherein the first upper side surface couples with the second upper side surface, and wherein the first upper side surface is perpendicular to the second upper side surface; and
wherein the first upper side surface forms a right angle with the lower top surface, and wherein the second upper side surface forms a right angle with the lower top surface.
